(19) United States
(12) Patent Application Publication
(10) Pub. No.: US 2025/0218847 A1
(43) Pub. Date: Jul. 3, 2025

(54) CONFIGURABLE CARRIER FOR TRANSFER AND SELF-ASSEMBLY OF MULTIPLE INTEGRATED CIRCUIT DEVICES

(71) Applicant: Intel Corporation, Santa Clara, CA (US)

(72) Inventors: Veronica A. Strong, Brussels (BE); Feras Eid, Chandler, AZ (US); Chien-An Chen, San Jose, CA (US); Wenhao Li, Chandler, AZ (US); Bhaskar Jyoti Krishnatreya, Hillsboro, OR (US); Thomas Sounart, Chandler, AZ (US); Adel Elsherbini, Chandler, AZ (US); Kimin Jun, Portland, OR (US); Johanna Swan, Scottsdale, AZ (US)

(73) Assignee: Intel Corporation, Santa Clara, CA (US)

(21) Appl. No.: 18/401,041

(22) Filed: Dec. 29, 2023

(51) Int. Cl. H01L 21/683; H01L 23/00

(52) U.S. Cl. CPC H01L 21/6835; H01L 24/80; H01L 2221/68368; H01L 2224/80006; H01L 2224/80097; H01L 2224/80895; H01L 2224/80896; H01L 2924/40

(57) ABSTRACT

A first carrier comprises a plurality of regions. Each region comprises a first zone and a second zone. The second zone comprises a portion that surrounds the first zone. Each first zone comprises a hydrophilic surface, and each second zone comprises a hydrophobic surface. A first liquid is deposited on the first carrier. The plurality of regions are aligned with a plurality of dies on a second carrier. The dies are transferred from the second carrier to the first carrier. A second liquid is deposited on a substrate, which includes a plurality of bond areas. Each die bond area comprises a hydrophilic surface. The dies are transferred from the first carrier to the substrate.

### BACKGROUND

In electronics manufacturing, multiple integrated circuit (IC) devices are typically fabricated on a single semiconductor wafer. This approach enables high-volume and efficient production of individual IC devices. After the IC devices are fabricated, the devices are singulated and multiple IC devices may be transferred together to another carrier wafer, to a target wafer, or to a die.

For technologies like die-to-wafer (D2 W), die-to-die (D2D), and collective die-to-wafer (coD2 W) bonding, pick and place tools are typically used to transfer singulated die from their original source to either a carrier wafer or directly onto a target wafer for bonding. Pick and place tools use a vacuum tip for transferring and placing dies. Use of pick and place tools sometimes leaves an organic residue on a surface of the die or results in damage to the die. To eliminate residue, prevent possible damage, or both, cleaning steps or placing protective films on the die surface may need to be added to the manufacturing process.

Protection layers have several disadvantages. They add steps and complexity to the manufacturing process. In addition, the protective films may need to be removed prior to hybrid bonding. The removal of some protective films may add residue, oxidize or etch copper on surfaces, or require additional heating at elevated temperatures, thus compromising the hybrid bonding surface.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a flow diagram of methods for configuring a carrier for transferring a particular set of IC devices from a source location to a target location, in accordance with some embodiments;

FIG. 2 is a plan view illustrating a carrier for transferring a particular set of IC devices from a source location to a target location, in accordance with some embodiments;

FIGS. 3A to 3E are plan views illustrating example regions of the carrier depicted in FIG. 2, in accordance with some embodiments;

FIG. 4A and FIG. 4B are cross-sectional side views of a section of the carrier depicted in FIG. 2, according to various embodiments;

FIG. 5A to FIG. 5D are cross-sectional side views of the section of a carrier depicted FIG. 4B after various stages of manufacturing, according to various embodiments;

FIGS. 6A and 6B are cross-sectional side views of a section of a carrier section after topography modification operation, according to various embodiments;

FIG. 7A to FIG. 7H illustrate cross-sectional side views of a section of a carrier after various stages of manufacturing, in accordance with some embodiments;

FIG. 8A to FIG. 8G illustrate cross-sectional side views of a section of a carrier after various stages of manufacturing, in accordance with some embodiments;

FIG. 9 illustrates a flow diagram of methods for transferring a particular set of IC devices from a source location to a target location, in accordance with some embodiments; and

FIG. 10A to FIG. 10F illustrate cross-sectional side views of a section of a carrier after various stages of transfer of multiple IC devices, in accordance with some embodiments.

### DETAILED DESCRIPTION OF EXEMPLARY EMBODIMENTS

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

Embodiments disclosed herein are directed to a reprogrammable carrier that may be used to transfer heterogenous IC devices from a source wafer to a target wafer. The reprogrammable carrier permits mass transfer of chips and/or chiplets without requiring a tool with a mechanical vacuum tip. The reprogrammable carrier may be used for die-to-wafer (D2 W) transfers, die-to-die (D2D) transfers, or collective D2 W (coD2 W) transfers. The reprogrammable carrier includes hydrophilic and hydrophobic zones. A liquid on a surface of the carrier is attracted to the hydrophilic zones and repelled from the hydrophobic zones. Die transfer is accomplished in a self-aligning manner by beads of liquid on the surface of the carrier being attracted to hydrophilic zones. Beads of another liquid on the surface of the target wafer are attracted to hydrophilic zones on the target. The die being transferred attach to one or more beads on the surface of the carrier and to one or more beads on the surface of the target wafer.

An advantage of embodiments described herein is that disadvantages that sometimes result from the use pick and place tools may be avoided, e.g. surface residue, possible damage to IC die, and/or extra processing steps.

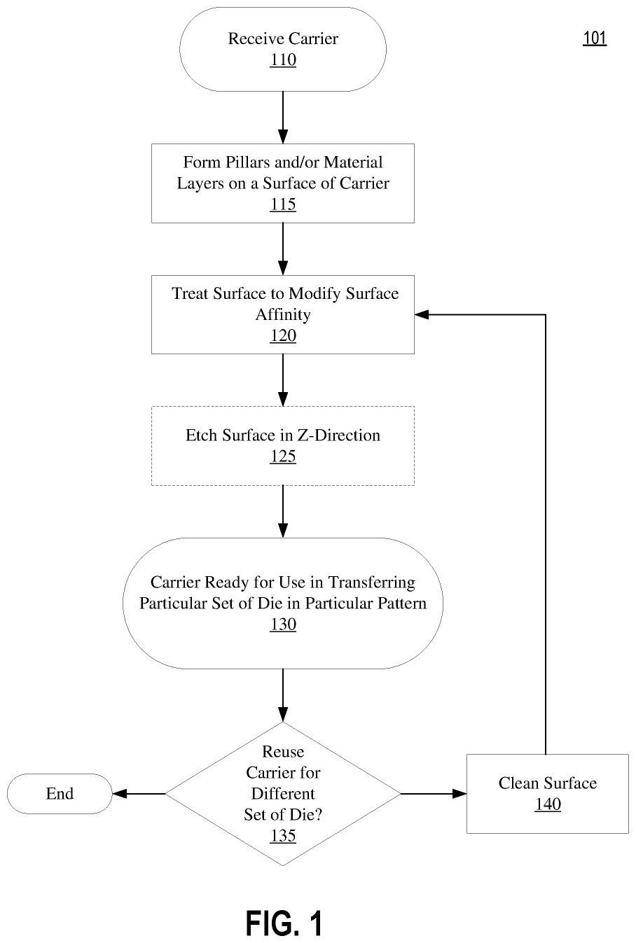

A variety of fabrication methods may be practiced to form a configurable carrier for transferring multiple IC devices having one or more of the features described herein. FIG. 1 illustrates a flow diagram of methods 101 for configuring a carrier for transferring a particular set of IC devices from a source location to a target location, in accordance with some embodiments. In particular, FIG. 1 illustrates a flow diagram of methods 101 for forming a plurality of regions on a carrier, each region comprising a first zone that includes a hydrophilic surface and a second zone that includes a hydrophobic surface, in accordance with some embodiments.

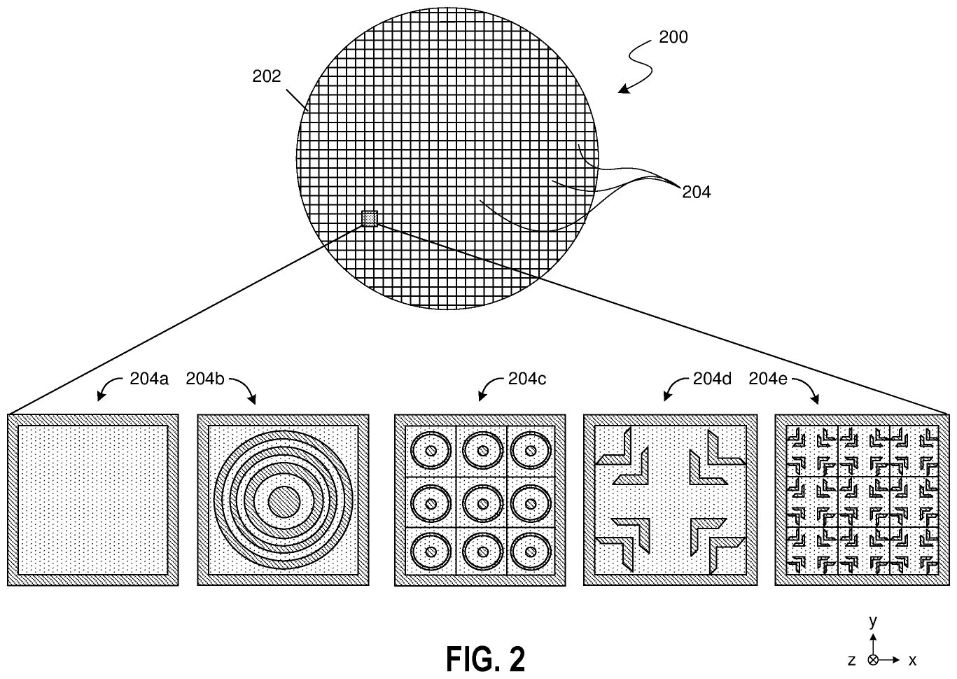

Methods 101 begin at block 110 where a carrier is received. The carrier may be prepared upstream of methods 101 and may be in a wafer format, a large panel format, or the like. The carrier may be a silicon wafer, copper clad laminate panel (CCL), or a glass panel. The carrier may comprise one or more materials, or one or more material layers. Material layers may include organic material, dielectric material or a metal. FIG. 2 is a plan view that illustrates a front-side surface 202 of the carrier 200, in accordance with some embodiments. Methods 101 describe how a plurality of regions 204 may be formed on front-side surface 202.

Returning to FIG. 1, methods 101 continue at block 115 where features (e.g., pillars), material layers, or both features and material layers formed on the front-side surface 202 of the carrier 200. One or more material layers may be deposited on front-side surface 202 using any suitable known process. In addition, features may be fabricated with any process known to be suitable for forming features in the carrier material or any material layers deposited on front-side surface 202. For example, features may be formed in an additive process, such as one that includes depositing a material layer in desired areas. Alternatively, features may be formed in a subtractive process, such as one that includes depositing a material layer over front-side surface 202 and chemically etching material not covered with a mask. In some embodiments, features may be formed using a combination of additive and substrative techniques. In some examples, features may be formed using lithography, chemical vapor deposition (CVD), or physical vapor deposition (PVD), ink-jet printing, nanoimprinting, micro-imprinting and the like.

In some embodiments, dry texture material (DTM) pillars may be formed at block 115. DTM pillars may be formed out of silicon, polymers, or inorganic material using a lithography or a stamping process. DTM pillars may extend vertically from a base to a top side opposite the base. DTM pillars include sidewalls between the base and the top side. The top side of a DTM pillar is the highest point at the front-side surface 202. The top side of a DTM pillar may have a have a concave shape similar in appearance to a suction cup.

In some examples, a layer of silicon dioxide is formed on front-side surface 202 and conventional pillars are etched in the silicon dioxide layer.

In some embodiments, one or more material layers are formed on the front-side surface 202 at block 115. For example, a dielectric layer may be formed on front-side surface 202, with a metal layer being formed over the dielectric layer. In other examples, a first dielectric layer may be formed on the front-side surface 202, with a second a dielectric layer formed over the first dielectric layer. The second dielectric layer may have a different composition than the first dielectric layer.

The composition of material in a metal layer formed over a dielectric layer on front-side surface 202 may vary with implementation. In some embodiments, the metal layer is copper, or _ruthenium, tungsten, or metal alloys.

The composition of material in a dielectric layer formed on front-side surface 202 or a second dielectric layer formed over a first dielectric layer on the front side surface may vary with implementation. In some embodiments, the dielectric material is an organic dielectric, such as, an epoxy resin, phenolic-glass, or a resinous film such as the GX-series films commercially available from Ajinomoto Fine-Techno Co., Inc. (ABF). The dielectric material may comprise epoxy resins (e.g., an acrylate of novolac such as epoxy phenol novolacs (EPN) or epoxy cresol novolacs (ECN)). In some specific examples, the dielectric material is a bisphenol-A epoxy resin, for example including epichlorohydrin. In other examples, the dielectric material includes aliphatic epoxy resin.

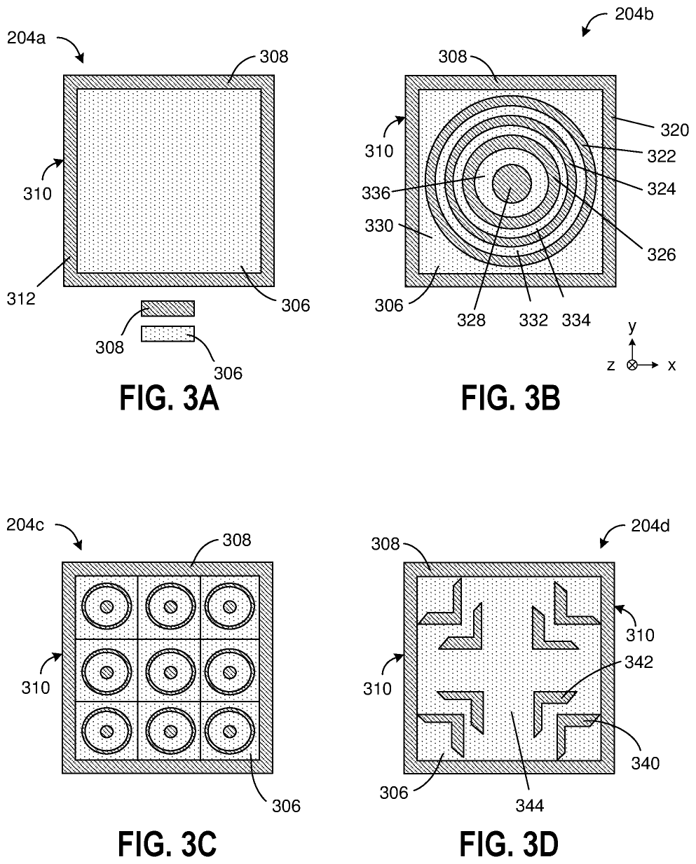

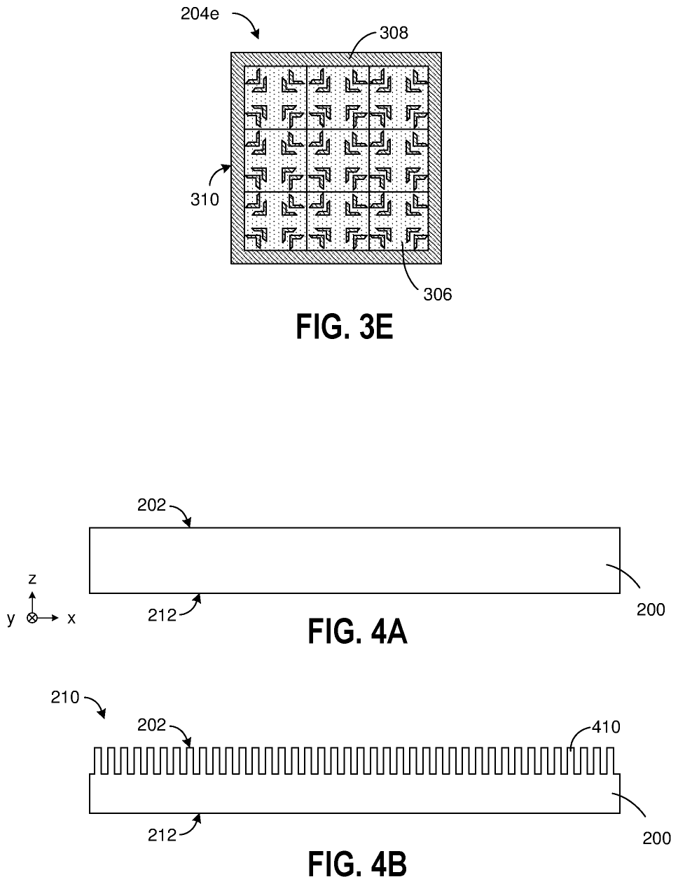

Returning to FIG. 1, methods 101 continue at block 120 where regions 204 on front-side surface 202 are defined and zones are created within each region. Referring again to FIG. 2, the carrier 200 illustrates a plurality of regions 204 on front-side surface 202 of carrier 200, in accordance with some embodiments. FIG. 2 depicts enlarged examples of a region 204. In particular, regions 204a, 204b, 204c, 204d, and 204e are shown. Further enlarged versions of regions 204a, 204b, 204c, 204d, and 204e are depicted in FIGS. 3A to 3E. As illustrated in FIGS. 3A to 3E, each region 204 includes one or more first zones 306 and one or more second zones 308. The zones within the regions may be formed directly on front-side surface 202 through use of standard lithographic methods and/or micro or nanoimprinting, or ink-jet printing or any technique that can modify surface energy to form either a hydrophilic or a hydrophobic surface. In some embodiments, formation of a zone may include forming or depositing a layer or film on front-side surface 202. In some embodiments, formation of a zone may include modifying the material of which the front-side surface 202 is comprised, e.g., a chemical modification of the surface, a surface functionalization, or a plasma surface functionalization. In embodiments, each instance of a region 204 may include the same first and second zones, wherein each first zone comprises a hydrophilic surface, and each second zone comprises a hydrophobic surface. Within each region 204, the first and second zones have the same dimensions and positions. As such, each region 204 may be considered a repeating unit, each unit with a defined architecture and pattern. In some embodiments, two or more types of regions 204 may be defined on front-side surface 202, wherein each type of region is a repeating unit, i.e., includes the same first and second zones. For example, a first type of region 204 may include first and second zones that align with a single large die, and a second type of region 204 may include first and second zones that align with two small dies. In another example of a carrier having two types of regions, a carrier may include multiple instances of region 204b and multiple instances of region 204c. The repeating regions 204 may be used to perform local or global transfer of multiple IC devices. An advantage of embodiments described herein is that a region 204 may transfer a single die or multiple dies, and the dies may be heterogenous, e.g., die may be of a variety of different sizes. A further advantage is that each region 204 enables a particular die to transfer to a specific location on a target surface.

As may be seen in FIG. 2, the plurality of regions 204 may be arranged in a pattern corresponding to how IC dies are arranged on the wafer or panel the dies are to be transferred from. Regions 204 may be rectangular, but this is not essential. In some embodiments, regions 204 may be in any suitable shape, such circular, octagonal, L-shaped (gnomon), T-shaped, cross or x-shaped, etc.

FIGS. 3A to 3E are plan views that illustrate examples of regions 204 shown in FIG. 2, in accordance with some embodiments. FIG. 3A illustrates an example region 204a that includes a first zone 306 and a second zone 308. Region 204a also includes four sides 310. In embodiments, the first zone 306 is hydrophilic and the second zone 308 is hydrophobic. In some embodiments, the second zone 308 surrounds the first zone 306. In some embodiments, the second zone 308 is at or includes a portion 312 that is at a side 310 or a perimeter of the region 204a. In some embodiments, the second zone (or a portion 312 of the second zone) is between the first zone 306 and the side 310.

FIG. 3B illustrates an example region 204b that includes a first zone 306 and a second zone 308. Region 204b also includes four sides 310. In embodiments, the first zone 306 is hydrophilic and the second zone 308 is hydrophobic. The first zone 306 includes portions 330, 332, 334, and 336. The second zone 308 includes portions 320, 322, 324, 326, and 328. As shown in the figure, some of the portions are concentric circular shapes. In some embodiments, a portion of the second zone 308 surrounds at least a portion of the first zone 306. For example, portion 320 of the second zone 308 surrounds all portions of first zone 306. As another example, portion 322 of the second zone 308 surrounds portions 332, 334, and 336 of first zone 306. In some embodiments, a portion of the second zone 308 is between at least a portion of the first zone 306 and side 310. For example, portion 326 of second zone 308 is between portion 336 of first zone 306 and side 310.

FIG. 3C illustrates an example region 204c that includes a first zone 306 and a second zone 308. Region 204c also includes four sides 310. In embodiments, the first zone 306 is hydrophilic and the second zone 308 is hydrophobic. The second zone 308 is at or includes a portion that is at a side 310 or a perimeter of the region 204c. Region 204c is divided into nine rectangular parts within the perimeter portion of second zone 308. Each part includes the same pattern. Each part includes three second zone 308 portions: a solid circular portion within a circular portion, which is in turn within a rectangular portion. Each part also includes two first zone 306 portions: an outer portion and inner portion. The outer portion of first zone 306 is between the rectangular portion of second zone 308 and the circular portion of second zone 308. The inner portion of first zone 306 is between the circular portion of second zone 308 and the solid circular portion of second zone 308 at the center of the part. Example region 204c may be used to transfer up to nine IC devices. FIG. 3C is missing the circular portion of the illustration.

FIG. 3D illustrates an example region 204d that includes a first zone 306 and a second zone 308. Region 204d also includes four sides 310. In embodiments, the first zone 306 is hydrophilic and the second zone 308 is hydrophobic. The second zone 308 is at or includes a portion that is at a side 310 or a perimeter of the region 204d. The second zone 308 of region 204d includes two chevron or “V” shaped portions in each corner. The chevron shapes include two diagonal stripes that meet at an angle forming a point. The points of the second zone portions point toward the interior of region 204d. The chevron shapes in a corner are arranged so that the point of the outer chevron 340 points at the intersection of the two stripes in the inner chevron 342. In some embodiments, a portion of the second zone 308, e.g., the portion at side 310, surrounds the first zone 306. In some embodiments, a portion of the second zone 308 is between at least a portion of the first zone 306 and side 310. For example, inner chevron 342 of second zone 308 is between portion 344 of first zone 306 and one of the sides 310. Example region 204d may be used to transfer one or two IC devices. Also missing the full illustration, please redo the figure.

FIG. 3E illustrates an example region 204d that includes a first zone 306 and a second zone 308. Region 204e also includes four sides 310. In embodiments, the first zone 306 is hydrophilic and the second zone 308 is hydrophobic. The second zone 308 is at or includes a portion that is at a side 310 or a perimeter of the region 204d. Region 204e is divided into nine rectangular parts within the perimeter portion of second zone 308. Each part includes the same pattern. Each part includes second zone 308 portions and first zone 306 portions that are similar to example region 204d. Each part includes two chevron or “V” shaped portions in each corner. Example region 204e may be used to transfer up to nine IC devices.

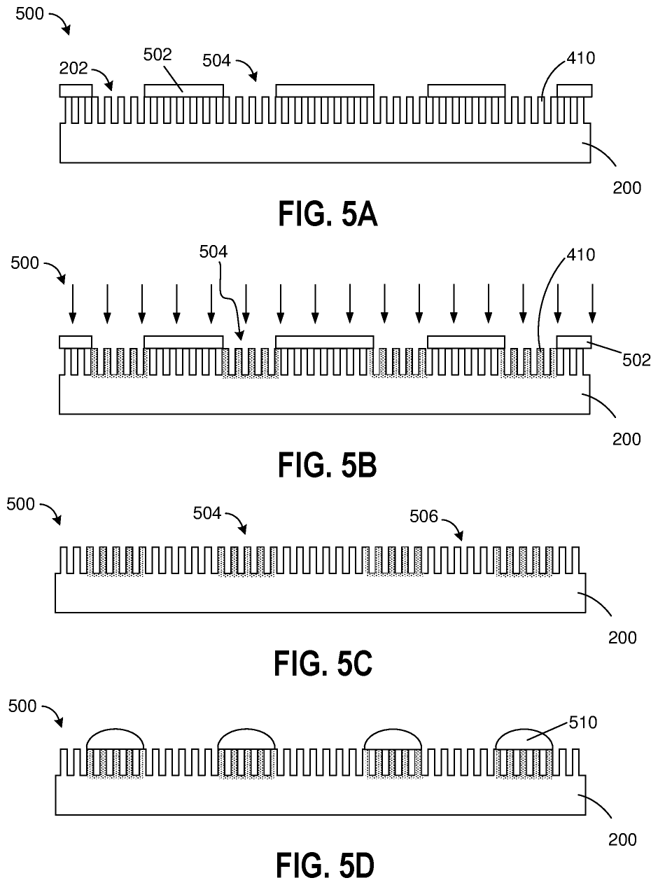

Operations at block 120 of methods 101 include defining regions on a carrier, and creating hydrophilic first zones and hydrophobic second zones within each region. Having described some examples of how regions may be arranged on a carrier, and how first and second zones may be arranged with a region, lithography methods for creating first and second zones is described below in FIG. 5A to FIG. 5D. Alternative starting carriers are described prior to the lithography methods. While FIG. 5A to FIG. 5D describe lithography methods, other methods for patterning zones on a carrier may be employed. For example, direct writing, nanoimprinting, stamp lift off process, or paste printing may be used to pattern zones on a carrier in some embodiments.

FIG. 4A and FIG. 4B are cross-sectional side views of a section 210 of carrier 200 of FIG. 2 according to various embodiments. As shown in FIG. 2, section 210 of carrier 200 includes two regions 204. FIG. 4A depicts the section of carrier 200 without pillars on front side surface 202. FIG. 4B depicts the section of carrier 200 after pillars 410 have been formed on front side surface 202. The pillars 410 may be formed at operation 115 as described above. In some embodiments, the pillars 410 may be DTM pillars. Carrier 200 includes a back side surface 212 opposite to front side surface 202.

FIG. 5A to FIG. 5D are side cross-sectional views of the section 210 of carrier 200 depicted FIG. 4B after various stages of manufacturing. It should be appreciated that the various stages of manufacturing depicted in FIG. 5A to FIG. 5D will appear similar for a section 210 of carrier 200 (without pillars) depicted FIG. 4A. Drawings of the carrier 200 without pillars are omitted so to not obscure features of various embodiments.

FIG. 5A is a cross-sectional side view of the section 210 of carrier 200 depicted FIG. 4B. FIG. 5A illustrates a carrier section 500 with pillars 410 after a patterned photoresist 502 is formed over front side surface 202. More particularly, FIG. 5A illustrates a photoresist 502 deposited over front side surface 202 using any suitable method, e.g., spin coating. The photoresist may be either a positive or negative photoresist. The photoresist is shown after it has been patterned using any suitable technique. While depicted in FIG. 5A, the front side surface 202 in this example may be hydrophobic or include a hydrophobic layer. In other examples, front side surface 202 may be hydrophilic or include a hydrophilic layer.

FIG. 5B is a cross-sectional side view of carrier section 500 after front side surface 202 has been treated to modify the surface energy within openings (zones 504) in the photoresist 502, e.g., the pillars 410. In the embodiment of FIG. 5B, zones 504 on front side surface 202 are modified to be hydrophilic. In other embodiments, zones 504 on front side surface 202 are modified to be hydrophobic. The front side surface 202 within zones 504 may be modified with a chemical process, plasma process, or combination of both processes. Chemical processes can include the depositing self-assembled monolayers on the surface, coating the surface with a polymer, applying acid etchants to the surface. Any suitable chemical process that modifies the surface energy to make the surface hydrophobic or hydrophilic may be employed. Plasmas can include oxides, argon, and fluorides, e.g., NF3. In addition to SAMs and polymers, metal organics, fluorinated acrylic polymers, or a combination of materials may be provided on front side surface 202 within zones 504 to form a desired difference between hydrophobic and hydrophilic zones.

FIG. 5C is a cross-sectional side view of carrier section 500 after photoresist 502 has been removed from front side surface 202. In the example of FIG. 5C, carrier section 500 is left with hydrophilic zones 504 and hydrophobic zones 506. The hydrophobic zones 506 are located where photoresist 502 was present. Photoresist 502 may be removed using any suitable process.

FIG. 5D is a cross-sectional side view of carrier section 500 after a liquid 510 has been applied to front side surface 202. In some embodiments, the liquid is water. In other embodiments, the liquid may have additives, or have a particular acidity or basicity. In some embodiments, the liquid maybe a low vapor pressure coating. Liquid 510 may be applied as a spray or with spin coating. As can be seen in FIG. 5D, the liquid 510 forms bead at the locations of the hydrophilic zones 504. In embodiments, liquid 510 at each of these locations have the same contact angle.

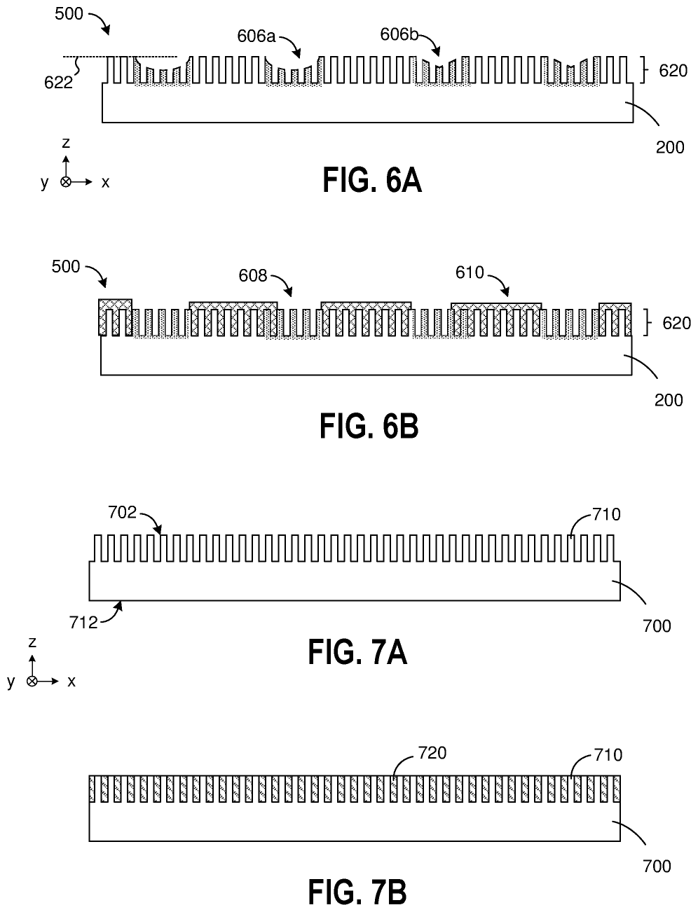

Returning to FIG. 1, methods 101 continue at block 125 where the topography of front side surface 202 carrier section 500 may be modified. The topography modifications at block 125 are optional. One example method for modifying front side surface 202 is a chemical etch process. Another example method for modifying front side surface 202 is a material deposition process. Operations at block 125 may be performed at any suitable stage of manufacturing. For example, surface topography may be performed before or after surface affinity for liquid modifications at block 120. FIG. 6A is a cross-sectional side view of carrier section 500 after an etch operation. In some embodiments, carrier 200 comprises a material layer 620 on a side, and the etch operation is performed in the material layer 620. In some embodiments, a material layer is absent and the etch operation is performed in the carrier. In the shown example, etch operations are performed in the first zones 606, which may be hydrophilic. The etch process may create a recess with a curved surface, e.g., first zone 606a, or a recess with substantially straight surfaces, e.g., first zone 606b. A result of the etch process is that the first zone may comprise a surface that is concave with respect to a plane 622 of the material layer 620 or concave with respect to a plane of the surface of the carrier. In some embodiments, the area adjacent to a first zone may be built up. For example, FIG. 6B illustrates a material, e.g., dielectric or metal, deposited in second zones 610, which are adjacent to hydrophilic zones 608. Second zones 610 may have an upper surface that is above the upper surface of the adjacent zones 608.

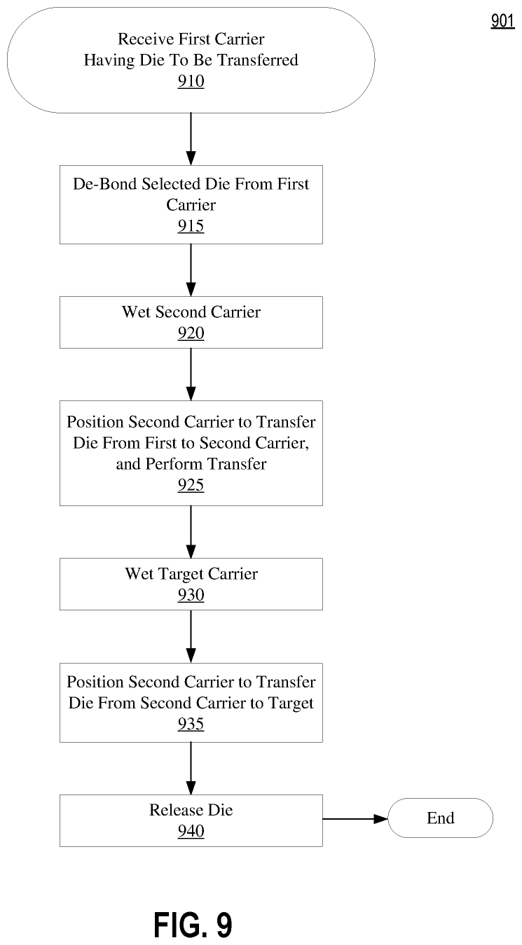

Returning to FIG. 1, methods 101 continue at block 130 where the configuring of a carrier for transferring a particular set of IC devices is completed. At block 130, the carrier is ready to be used in die transfer operations. Methods for transferring a die are described below with respect to FIG. 9.

Still referring to FIG. 1, methods 101 continue at block 135 where a decision can be made to either end the methods or reconfigure the carrier for use with another set of IC dies. It may be desired to reconfigure the carrier because may not be performing satisfactorily for some reason, or there may be a need to transfer different sets of dies because a process has been updated or changed. It may be desired to reconfigure the carrier for a new product. For example, it may be desired to transfer a different number of dies or dies of different sizes as compared with the carrier's current configuration of regions and zones. If it is desired to change the configuration of regions and/or zones on a carrier, the front side surface 202 is cleaned at block 140. Operations at block 140 may include an O2 plasma, chemical strip, or wet clean, or a combination of these processes to remove material from both the hydrophilic zones and the hydrophobic zones. From block 140, methods 101 return to block 120 where operations to define regions on the carrier are performed, and hydrophilic first zones and hydrophobic second zones are created within each region.

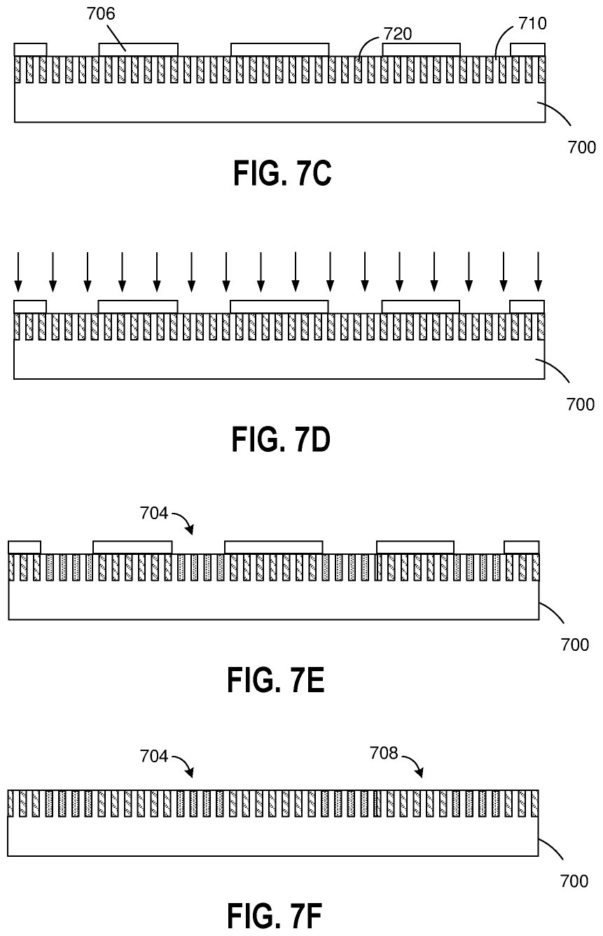

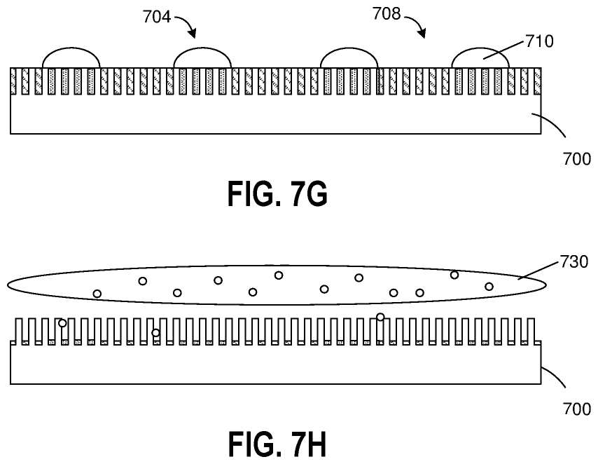

FIG. 7A to FIG. 7H illustrate cross-sectional side views of a section of a carrier 700 after various stages of manufacturing, in accordance with some embodiments. The carrier 700 may be the same as or similar to the carrier 200 described herein, e.g. a wafer or a panel comprised of any of the materials described herein for carrier 200. FIG. 7A shows carrier 700 after a plurality of pillars have been formed on front side surface 702. In some embodiments, pillars may not be formed on front side surface 702, e.g., carrier 700 may be similar to carrier 200 depicted in FIG. 4A. It is not essential that front side surface 702 include pillars. However, if pillars are included, they may be formed using a lithographic process, ink jet printing, a transfer process, or any other suitable method. In some embodiments, pillars 410 may be DTM pillars. In some embodiments, pillars 410 may be silicon, a metal, a polymer, or inorganic material. Carrier 700 includes a back side surface 712 opposite to front side surface 702.

FIG. 7B shows carrier 700 after front side surface 702 has been coated with an adhesive layer 720, such as hexamethyldisilazane (HMDS), an organic polymer, a photo-imageable dielectric or a photoresist material. FIG. 7C shows carrier 700 after a mask 706 has been placed over front side surface 702. FIG. 7D shows carrier 700 being treated with ultraviolet (UV) light or plasma. This treatment causes the surface energy of the HMDS, organic polymer, photo-imageable dielectric, or photoresist film to be modified to create either hydrophilic surface or a hydrophobic surface. FIG. 7E shows carrier 700 after UV light or plasma treatment. In the example shown in FIG. 7, the surface energy within openings in adhesive layer 720 has been modified to create hydrophilic zones 704 on front side surface 702. FIG. 7F shows carrier 700 after mask 706 has been removed, revealing hydrophobic zones 708.

FIG. 7G is a cross-sectional side view of carrier 700 after a liquid 710 has been applied to front side surface 702. In some embodiments, the liquid is water. In other embodiments, the liquid may be an aqueous solution, an acidic or basic solution, or a low vapor pressure medium. Liquid 710 may be applied as a spray or with spin coating. As can be seen in FIG. 7G, the liquid 710 forms beads at the locations of the hydrophilic zones 704 and is absent from hydrophobic zones 708. In embodiments, liquid 710 at each of these locations may have the same contact angle. In FIG. 7G, the carrier 700 is ready to be used in die transfer operations. Methods for transferring a die are described below with respect to FIG. 9.

FIG. 7H is a cross-sectional side view of carrier undergoing a cleaning operation. As noted herein, it may be desired to change the configuration of regions and zones on the carrier. Before the carrier can be reconfigured for another configuration, front side surface 702 is cleaned. A cleaning operation 730 may include an O2 plasma, chemical strip, or wet clean, or a combination of these processes to remove material from both the hydrophilic zones and the hydrophobic zones.

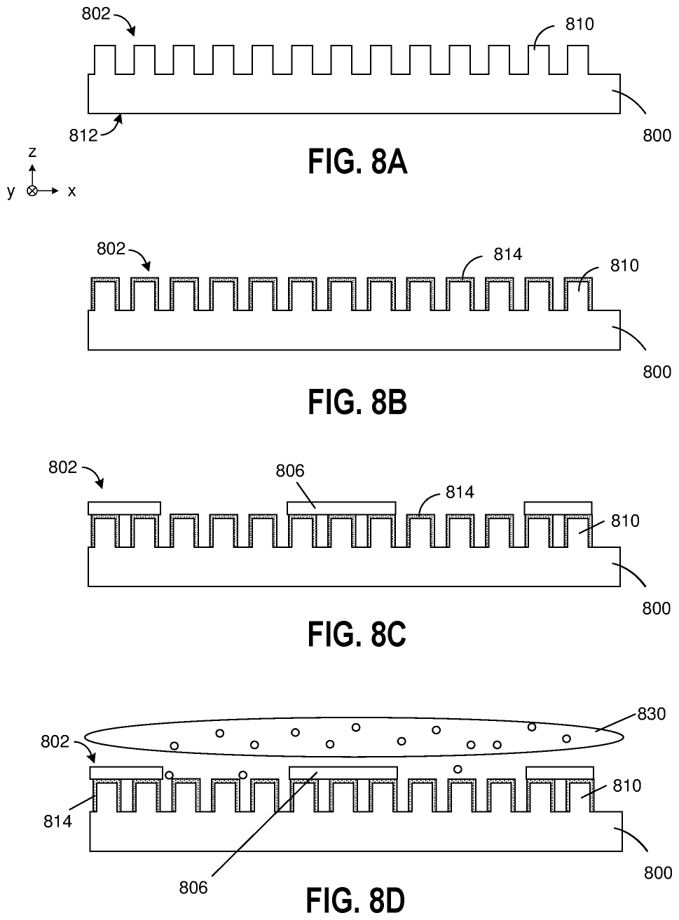

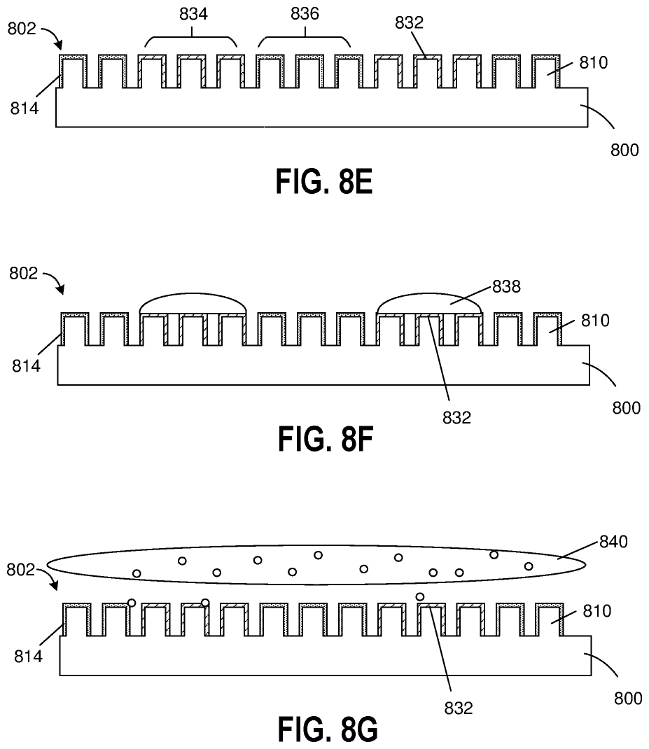

FIG. 8A to FIG. 8H illustrate cross-sectional side views of a section of a carrier 800 after various stages of manufacturing, in accordance with some embodiments. The carrier 800 may be the same as or similar to the carrier 200 described herein, e.g. a wafer or a panel comprised of any of the materials described herein for carrier 200. FIG. 8A shows carrier 800 after a plurality of pillars have been formed on front side surface 802. In some embodiments, pillars may not be formed on front side surface 802, e.g., carrier 800 may be similar to carrier 200 depicted in FIG. 4A. It is not essential that front side surface 802 include pillars. However, if pillars are included, they may be formed using a lithographic process, ink jet printing, a transfer process, or any other suitable method. In some embodiments, pillars 810 may be DTM pillars. In some embodiments, pillars 810 may be silicon, a metal, or a polymer. Carrier 800 includes a back side surface 812 opposite to front side surface 802.

FIG. 8B shows carrier 800 after front side surface 802 has been coated with silicon nitride (Si3N4). The silicon nitride coating 814 on the front side surface 802 and, in particular, the pillars 810, makes the surface hydrophobic. FIG. 8C shows carrier 800 after a mask 806 has been placed over front side surface 802. FIG. 8D shows carrier 800 being treated with plasma. Plasma treatment 830 causes the silicon nitride to be modified into silicon dioxide, thereby creating hydrophilic surface on parts of the surface between mask 806. FIG. 8E shows carrier 800 after being treated with plasma, and after the mask 806 has been removed. As illustrated in FIG. 8E, front side surface 802 includes first zones 834 in which the surface is coated with silicon dioxide 832, and second zones 836 in which the surface is coated with silicon nitride 814.

FIG. 8F is a cross-sectional side view of carrier 800 after a liquid 838 has been applied to front side surface 802. As can be seen in FIG. 8F, the liquid 838 forms beads at the locations of the hydrophilic zones 834. In FIG. 8G, the carrier 800 is ready to be used in die transfer operations. Methods for transferring a die are described below with respect to FIG. 9.

FIG. 8G is a cross-sectional side view of carrier 800 undergoing a cleaning operation 840. As noted herein, it may be desired to change the configuration of regions and zones on the carrier. Before the carrier can be reconfigured for another configuration, front side surface 802 is cleaned. A cleaning operation 840 may include a wet etch to remove the silicon nitride and silicon dioxide. Cleaning operation 840 may also include treating the surface with a dilute hydrofluoric acid (DHF) solution and phosphoric acid. In addition, cleaning operation may include an RCA cleaning process. In some embodiments, the cleaning operation may include an O2 plasma, chemical strip, or wet clean, or a combination of these processes to remove material from both the hydrophilic zones and the hydrophobic zones. At the conclusion of cleaning operation 840, front side surface 802 is returned to its original state, as shown in FIG. 8A. Once returned to its original state, carrier 880 may be reprogrammed for transferring a different set of IC die.

FIG. 9 illustrates a flow diagram of methods 901 for transferring a particular set of IC devices from a source location to a target location, in accordance with some embodiments. Methods 901 enable multiple IC dies to be simultaneously transferred from a standard carrier to target wafer. Methods 901 begin at block 910 where a first carrier is received. The IC dies to be transferred may be attached to the first carrier with a releasable die attach film. At block 915, selected IC die are de-bonded from the first carrier.

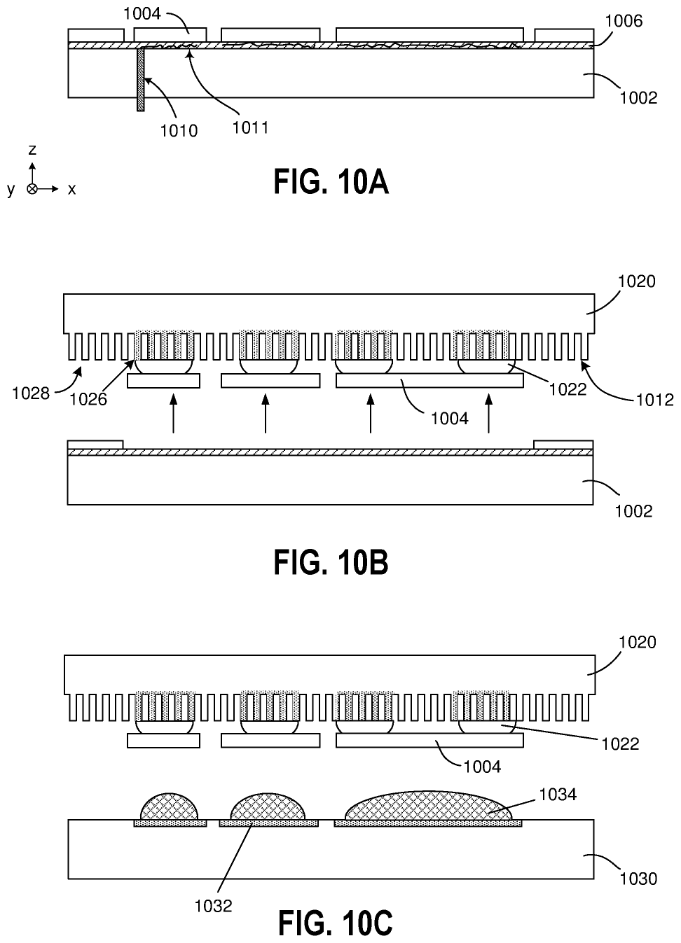

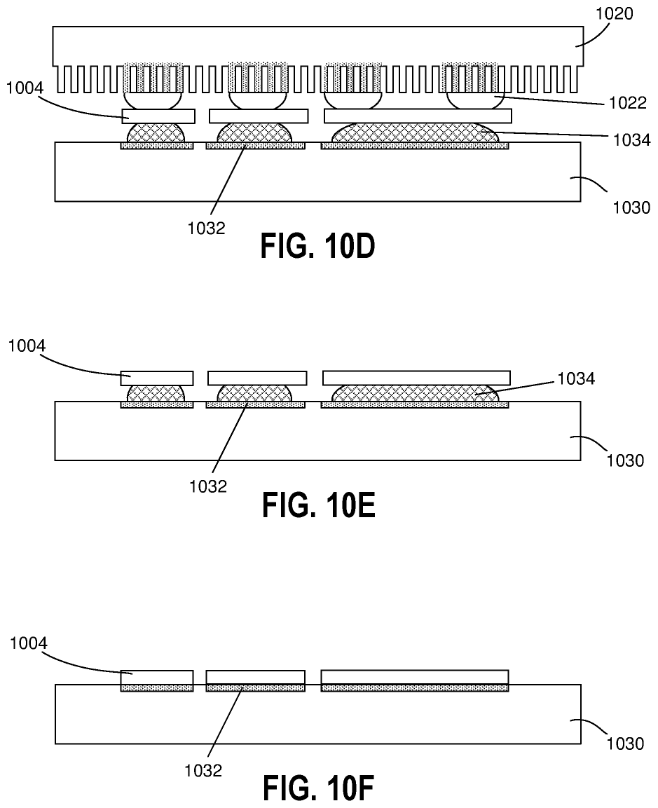

FIG. 10A is a cross-sectional side view of a section of a first carrier 1002. Multiple IC dies 1004 are attached to the first carrier 1002 with a releasable die attach film 1006. FIG. 10A illustrates selected IC die 1004 being loosened or released by a laser de-bond process. Laser light 1010 causes releasable die attach film 1006 to lose its adhesiveness below selected IC die, as indicated by lines 1011.

Returning to FIG. 9, methods 901 continue at block 920 where a first liquid is deposited on a surface of a second carrier, which may be a configurable carrier for transferring multiple IC devices, as described herein. The second carrier has a plurality of regions, each region including a first zone and a second zone. Each first zone includes a hydrophilic surface, and each second zone includes a hydrophobic surface. The first liquid forms beads over the hydrophilic surfaces. At block 925, the second carrier is placed in alignment with and at close distance to the first carrier, and the selected die are transferred from the first carrier to the second carrier. The selected die may be picked up because Van der Waals forces between the beads of the liquid and the die are greater than the adhesive and gravitational forces holding the die in place on the first carrier.

FIG. 10B is a cross-sectional side view of a section of a second carrier 1020 after a first liquid 1022 has been applied to front side surface 1012 of the second carrier 1020. The second carrier 1020 includes first zones 1026 and second zones 1028. In some embodiments, the first zones 1026 include hydrophilic surfaces, and second zones 1028 include hydrophobic surfaces. In addition, FIG. 10B illustrates the first carrier 1002 after selected IC dies 1004 have been transferred to second carrier 1020. In some embodiments, liquid 1022 is water. In other embodiments, the liquid 1022 may be an aqueous solution, be acidic or basic solution, or a low vapor pressure solution. Liquid 1022 may be applied as a spray or with spin coating. The liquid 1022 may form beads at the locations of first zones 1026. In embodiments, liquid 1022 at each of these locations have the same contact angle.

Returning to FIG. 9, methods 901 continue at block 930 where a second liquid is deposited on a surface of a target carrier or target wafer. The second liquid may form beads at the locations intended for receiving the selected IC die. These locations on the surface of the target carrier may be hydrophilic, include metal conductive contacts, and be referred to herein as “bonding locations.” The second liquid may be applied in the same manner as the first liquid 1022. The second liquid may differ from the first liquid 1022 in that it may exert a greater adhesive force on the selected dies 1004 than the first liquid. In other embodiments, the second liquid may be an alcohol, an aqueous solution, an acidic or basic solution, or a low vapor pressure solution. Still referring to FIG. 9, methods 901 continue at block 935 where the second carrier is placed in a position in preparation to transfer IC devices from the second carrier to the target carrier or wafer. FIG. 10C is a cross-sectional side view of a section of second carrier 1020 and a target carrier 1030. In the figure, the second carrier 1020 is close to target carrier 1030 and aligned with bonding locations 1032 on the target carrier. FIG. 10C also illustrates the target carrier 1030 after beads of second liquid 1034 are disposed over the bonding locations 1032. FIG. 10D is a cross-sectional side view of a section of second carrier 1020 and a target carrier 1030 after selected IC dies 1004 are placed in direct contact with second liquid 1034.

Returning to FIG. 9, methods 901 continue at block 940, where the selected IC die are released. In some embodiments, the second carrier 1020 may be heated to diminish adhesion force between first liquid 1022 and selected IC die 1004. In other embodiments, the humidity in the local environment may be changed to drive release of the selected IC die 1004 from the second carrier 1020. After the IC die 1004 are released from the second carrier 1020 may be relocated and the second liquid 1034 may be removed. Like the first liquid, the second liquid 1034 may be removed by evaporation. Evaporation may be induced by heating the target carrier 1030 or altering the humidity in the local environment. FIG. 10E is a cross-sectional side view of a section of target carrier 1030 after selected IC 1004 die have been released from the second carrier 1020. FIG. 10F is a cross-sectional side view of a section of target carrier 1030 after second liquid 1034 has evaporated. After block 940, methods 901 may end. With the selected IC die 1004 aligned with and in contact with bonding locations 1032, IC die 1004 may be bonded to the target carrier 1030. In embodiments, the IC die 1004 may be bonded to the target carrier 1030 through hybrid bonding. In other embodiments, the IC die 1004 may be bonded to the target carrier 1030 with conventional solder bonds.

Hybrid bonding is a technique in which bonds are formed between corresponding metallic features, e.g., bond pads on two dies, e.g., IC die 1004 and target carrier 1030. The metal features on each die are embedded within an insulator. In addition, hybrid bonding may include fusing the insulator (dielectric) material of the respective dies. Accordingly, a hybrid bonded interface may include both metallurgically interdiffused metals and chemically bonded insulators (dielectric).

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the disclosure is not limited to the embodiments so described but can be practiced with modification and alteration without departing from the scope of the appended claims. For example, the above embodiments may include specific combinations of features as further provided below.

Example 1: An apparatus, comprising: a carrier comprising a plurality of regions on a side, each region comprising a first zone and a second zone, wherein the second zone comprises a portion that surrounds the first zone; and wherein each first zone comprises a hydrophilic surface, and each second zone comprises a hydrophobic surface.

Example 2: The apparatus of example 1, further comprising a material layer on the side, wherein the material layer comprises hexamethyldisilazane (HMDS), an organic polymer, a photo-imageable dielectric or a photoresist material.

Example 3: The apparatus of example 1, further comprising a material layer on the side, wherein each first zone comprises silicon dioxide and each second zone comprises silicon nitride.

Example 4: The apparatus of example 1, further comprising a material layer on the side, wherein the material layer comprises a self-assemble monolayer (SAM), a polydimethylsiloxane (PDMS), a polymethyl methacrylate (PMMA) acrylic, a polytetrafluoroethylene (PTFE) polymer, a polymer, a fluorinated acrylic polymer, a metal, an organic material, or an inorganic material.

Example 5: The apparatus of any of examples 1 through 4, wherein the portion of the second zone is a first portion, the second zone further comprising a second portion, wherein first portion surrounds the second portion.

Example 6: The apparatus of any of examples 1 through 5, wherein each region corresponds with a footprint of one or more die.

Example 7: The apparatus of example 1, further comprising a material layer on the side, wherein the material comprises a plurality of pillars.

Example 8: The apparatus of example 7, wherein each pillar of the plurality of pillars comprises a concave surface and a bottom surface opposite to the concave surface, wherein the bottom surface contacts the carrier.

Example 9: The apparatus of any of examples 1 through 8, wherein the carrier comprises silicon, glass, or an organic material.

Example 10: The apparatus of example 1, further comprising a material layer on the side, wherein the first zone is concave with respect to a plane of the material layer.

Example 11: A method, comprising: receiving a carrier comprising a material at a first side; forming a mask over the first side to define a plurality of regions, and a first zone and a second zone within each region, wherein the second zone comprises a portion that surrounds the first zone; treating the first zones with a process to form a hydrophilic surface within the first zones; and removing the mask.

Example 12: The method of example 11, further comprising forming a material layer over the first side, wherein the material layer comprises hexamethyldisilazane (HMDS), an organic polymer, a photo-imageable dielectric or a photoresist material.

Example 13: The method of example 11, further comprising a material layer over the first side, wherein the material layer comprises a self-assemble monolayer (SAM), a polydimethylsiloxane (PDMS), a polymethyl methacrylate (PMMA) acrylic, a polytetrafluoroethylene (PTFE) polymer, a polymer, a fluorinated acrylic polymer, a metal, an organic material, or an inorganic material.

Example 14: The method of example 11, wherein the process is a plasma process, and the plasma is derived from a gas comprising an oxide, nitride, argon, hydrogen, or a fluoride.

Example 15: The method of example 11, further comprising forming a material layer over the first side and forming a plurality of pillars in the material layer.

Example 16: The method of example 11, further comprising forming a material layer over the first side and etching the first zones so that the first zones are below a plane of the material layer.

Example 17: A method comprising: receiving a first carrier comprising a plurality of regions, each region comprising a first zone and a second zone, wherein the second zone comprises a portion that surrounds the first zone; providing a first liquid at the first zones; placing the first liquid in contact with a plurality of die on a second carrier; transferring the plurality of die from the second carrier to the first carrier; placing the plurality of die in contact with a second liquid, wherein the second liquid is at bonding location on a substrate; and transferring the plurality of die from the first carrier to the substrate.

Example 18: The method of example 17, wherein a vapor pressure of the second liquid is different from a vapor pressure of the first liquid.

Example 19: The method of example 17 or example 18, further comprising heating the second carrier after placing the plurality of die in contact with the second liquid.

Example 20: The method of any of examples 17 through 19, wherein the first zone comprises a hydrophilic surface and the second zone comprises a hydrophobic surface.

Example 21: The method of any of examples 17 through 20, further comprising bonding the plurality of die to the substrate, wherein the bonding comprises hybrid bonding.

Example 22: The method of any of examples 17 through 21, further comprising releasing the plurality of die from an adhesive layer on the second carrier using a laser process.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should therefore be determined with reference to the appended claims, along with the full scope of equivalents to which such claims are entitled.

What is claimed is:

1. An apparatus, comprising:
a carrier comprising a plurality of regions on a side, each region comprising a first zone and a second zone, wherein the second zone comprises a portion that surrounds the first zone; and
wherein each first zone comprises a hydrophilic surface, and each second zone comprises a hydrophobic surface.

2. The apparatus of claim 1, further comprising a material layer on the side, wherein the material layer comprises hexamethyldisilazane (HMDS), an organic polymer, a photo-imageable dielectric or a photoresist material.

3. The apparatus of claim 1, further comprising a material layer on the side, wherein each first zone comprises silicon dioxide and each second zone comprises silicon nitride.

4. The apparatus of claim 1, further comprising a material layer on the side, wherein the material layer comprises a self-assemble monolayer (SAM), a polydimethylsiloxane (PDMS), a polymethyl methacrylate (PMMA) acrylic, a polytetrafluoroethylene (PTFE) polymer, a polymer, a fluorinated acrylic polymer, a metal, an organic material, or an inorganic material.

5. The apparatus of claim 1, wherein the portion of the second zone is a first portion, the second zone further comprising a second portion, wherein first portion surrounds the second portion.

6. The apparatus of claim 1, wherein each region corresponds with a footprint of one or more die.

7. The apparatus of claim 1, further comprising a material layer on the side, wherein the material layer comprises a plurality of pillars.

8. The apparatus of claim 7, wherein each pillar of the plurality of pillars comprises a concave surface and a bottom surface opposite to the concave surface, wherein the bottom surface contacts the carrier.

9. The apparatus of claim 1, wherein the carrier comprises silicon, glass, or an organic material.

10. The apparatus of claim 1, further comprising a material layer on the side, wherein the first zone is concave with respect to a plane of the material layer.

11. A method, comprising:
receiving a carrier comprising a material at a first side;
forming a mask over the first side to define a plurality of regions, and a first zone and a second zone within each region, wherein the second zone comprises a portion that surrounds the first zone;
treating the first zones with a process to form a hydrophilic surface within the first zones; and
removing the mask.

12. The method of claim 11, further comprising forming a material layer over the first side, wherein the material layer comprises hexamethyldisilazane (HMDS), an organic polymer, a photo-imageable dielectric or a photoresist material.

13. The method of claim 11, further comprising a material layer over the first side, wherein the material layer comprises a self-assemble monolayer (SAM), a polydimethylsiloxane (PDMS), a polymethyl methacrylate (PMMA) acrylic, a polytetrafluoroethylene (PTFE) polymer, a polymer, a fluorinated acrylic polymer, a metal, an organic material, or an inorganic material.

14. The method of claim 11, wherein the process is a plasma process, and the plasma is derived from a gas comprising an oxide, nitride, argon, hydrogen, or a fluoride.

15. The method of claim 11, further comprising forming a material layer over the first side and forming a plurality of pillars in the material layer.

16. The method of claim 11, further comprising forming a material layer over the first side and etching the first zones so that the first zones are below a plane of the material layer.

17. A method comprising:
receiving a first carrier comprising a plurality of regions, each region comprising a first zone and a second zone, wherein the second zone comprises a portion that surrounds the first zone;
providing a first liquid at the first zones;
placing the first liquid in contact with a plurality of die on a second carrier;
transferring the plurality of die from the second carrier to the first carrier;
placing the plurality of die in contact with a second liquid, wherein the second liquid is at bonding location on a substrate; and
transferring the plurality of die from the first carrier to the substrate.

18. The method of claim 17, further comprising heating the second carrier after placing the plurality of die in contact with the second liquid.

19. The method of claim 17, wherein the first zone comprises a hydrophilic surface and the second zone comprises a hydrophobic surface.

20. The method of claim 17, further comprising bonding the plurality of die to the substrate, wherein the bonding comprises hybrid bonding.
